(19) United States
(12) Patent Application Publication
(10) Pub. No.: US 2002/0194557 A1
(43) Pub. Date: Dec. 19, 2002

(54) Built-in self test circuit using linear feedback shift register

(75) Inventor: Jin-Young Park, Yongin-shi (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 10/047,789

(22) Filed: Jan. 15, 2002

(30) Foreign Application Priority Data
Jun. 19, 2001 (KR) 2001-34736

(51) Int. Cl. G11C 29/00

(52) U.S. Cl. 714/718

(57) ABSTRACT

A built-in self test (BIST) circuit comprising a linear feedback shift register is disclosed. The BIST circuit comprises a controller for controlling a self-testing operation of a memory chip embedded in an integrated circuit, an address generator for generating pseudo-random address patterns under control of the controller, a data generator for producing test data associated with data backgrounds of the address bits under the control of the controller, and a comparator for comparing the test data with memory data output from the memory chip to detect a defect, if any, of the memory chip. The pseudo-random random pattern comprises a single-random pseudo-random address pattern.

### CROSS-REFERENCE TO RELATED APPLICATION

This application claims priority to Korean Patent Application No. 2001-34736, filed on Jun. 19, 2001, which is commonly owned and incorporated by reference herein.

### BACKGROUND

1. Technical Field

The present invention generally relates to a semiconductor integrated circuit and, more specifically, to a built-in self-test circuit embedded in a semiconductor integrated circuit.

2. Description of Related Art

Integrated circuit devices comprise a self-test circuit (referred to herein as “builtin self test (BIST) circuit”) to test, for example, combinational logic blocks, sequential logic blocks, memories, multipliers, and other embedded logic blocks, without having to use a tester or additional test equipment.

Examples of conventional BIST circuits are disclosed in U.S. Pat. No. 5,138,619, issued in 1992 to Fasang, entitled “Built-in self test for integrated circuit memory”, and U.S. Pat. No. 5,553,082, issued in 1996 to Conor, entitled “Built-in self test for logic circuit at memory array output”.

FIG. 1 is a block diagram showing a semiconductor-integrated device comprising a conventional BIST circuit. A conventional BIST circuit comprises a BIST controller 10, an address generator 20, a data generator 30, and a comparator 40.

The BIST controller 10 produces control signals for controlling the address generator 20, the data generator 30, the comparator 40, and a memory 50. The address generator 20 produces address bits A for writing/reading data (i.e., memory data) to/from the memory 50, and the data generator 30 provides reference data DI (that is compared with the memory data Dout) to the memory 50. The comparator 40 compares the memory data Dout with the reference data DI to detect defective data.

The “March” algorithm, as disclosed in U.S. Pat. No. 5,471,482, issued in 1995 to Byers et al., entitled “VLSI embedded RAM test” as applied to the BIST controller 10, performs a self-test procedure. The March 10N (or C—) algorithm is represented as follows:

(W_{D})↑(R_{D},W_{D}′)↑(R_{D}′,W_{D})↓(R_{D},WD′)↓(R_{D}′,W_{D}) (R_{D})

The arrow keys represent directions of address-counting, i.e., ↑, ↓, and respectively indicate an address increment, an address decrement, and one of the address increment and the address decrement. W and R respectively indicate a writing operation and a reading operation. Subscripts D and D′ respectively indicate a fixed data value and its inversion value. The symbol “( )” indicates a sequential process without an address change, and the symbol “,” demarcates the writing operation and the reading operation.

Assuming the BIST controller 10 implements the March ION test algorithm, the address generator 20 reiterates up-counting and down-counting operations, respectively, for incrementing and decrementing the addresses by using an up-counter and a down-counter. FIG. 2 shows an example of a synchronous counter for the up- or down-counter. The synchronous counter of FIG. 2 is an N-bit counter which comprises N-2 number of half adders HA₁ to HA_{N-2} and N number of flip-flops and uses carry propagation adders of the N-2 half adders. Each of the half adders HA₁ to HA_{N-2} produces a summation SUM and a carry CO in response to each of input data <1> to <N> and a carry CO from a former half adder. The flip-flops produce outputs Q<1> to Q<N> (i.e., Q<N:1>) in response to the summations SUMs and the carries COs provided from the half adders HA₁ to HA_{N-2}. The most significant bit (MSB) Q<N> among the output values Q<N:1> requires former carries of the former half adders HA₁ through HA_{N-2}. Thus, there is a critical timing path for generating the MSB among the counter paths.

When a conventional BIST circuit tests a high capacity memory (which is embedded in a semiconductor-integrated device) in high speed, the address generator 20 produces a large amount of address bits with a counter shown in FIG. 2. As a result, an optimal specification for designing the address generator may be inadequate due to the critical timing path of the counter.

To solve this problem, a BIST circuit may comprise a counter with a carry save adder instead of a carry propagation adder. However, the carry save adder occupies a larger area in a semiconductor-integrated device, thereby causing overhead, while it operates in high speed. A ripple counter may be used to decrease the size of the BIST circuit, but its asynchronous structure is not adaptable to a synchronous circuit architecture.

### SUMMARY OF THE INVENTION

It is, therefore, an object of the present invention to provide a BIST circuit capable of testing a memory chip in high speed without enlarging a circuit area.

It is another object of the present invention to provide a method for performing self-test on a memory chip in high speed.

According to one aspect of the present invention, a high speed BIST circuit comprising linear feedback shift registers (LFSRs) is provided. A BIST circuit comprises a controller for controlling a self-testing operation of a memory chip embedded in an integrated circuit; an address generator for generating pseudo-random address patterns under control of the controller; a data generator for producing test data associated with data backgrounds of the address bits under the control of the controller; and a comparator for comparing the test data with memory data output from the memory chip to detect a defect, if any, of the memory chip.

In one embodiment of the invention, the algorithm of the controller comprises a single-order test algorithm. The address generator comprises a plurality of linear feedback shift registers (LFSRs) serially connected to each other for producing the pseudo-random address patterns and a register controller for controlling the plurality of LFSRs. The address generator comprises a first linear feedback shift register for producing a first group of the pseudo-random address patterns by counting the address bits; a second linear feedback shift register serially connected to the first linear feedback shift register, and for producing a second group of the pseudo-random address patterns by counting the address bits; and a register controller for controlling the first and second linear feedback shift registers such that the first linear feedback shift register counts lower bits of the address bits and the second linear feedback shift register counts upper bits of the address bits or the first linear feedback shift register counts upper bits of the address bits and the second linear feedback shift register counts lower bits of the address bits the first vise versa.

According to another aspect of the present invention, a method for performing self-testing operation on a memory chip embedded in an integrated circuit is provided. The method comprises the steps of: counting address bits to produce test addresses of pseudo-random address patterns; producing test data according to the test address and data backgrounds of the address bits; and comparing the test data with memory data output from the memory chip to determine whether a defect exists.

These and other objects, aspects, features, and advantages of the present invention will become apparent from the following detailed description of preferred embodiments, which is to be read in connection with the accompanying drawings.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 is a block diagram of a semiconductor-integrated device comprising a conventional BIST circuit;

FIG. 2 is a block diagram of a conventional synchronous counter of an address generator of FIG. 1;

FIG. 3 is a schematic diagram of a semiconductor integrated device comprising BIST circuit according to an embodiment of the invention;

FIGS. 4A and 4B are exemplary diagrams illustrating address data backgrounds of 64 address bits to be assigned to a memory chip of FIG. 3; and

FIG. 5 is an exemplary diagram illustrating test addresses produced by an address generator of FIG. 3.

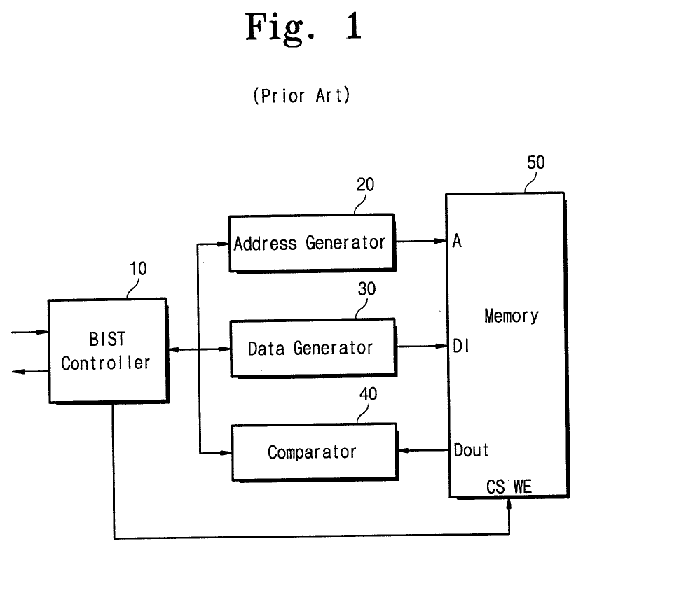

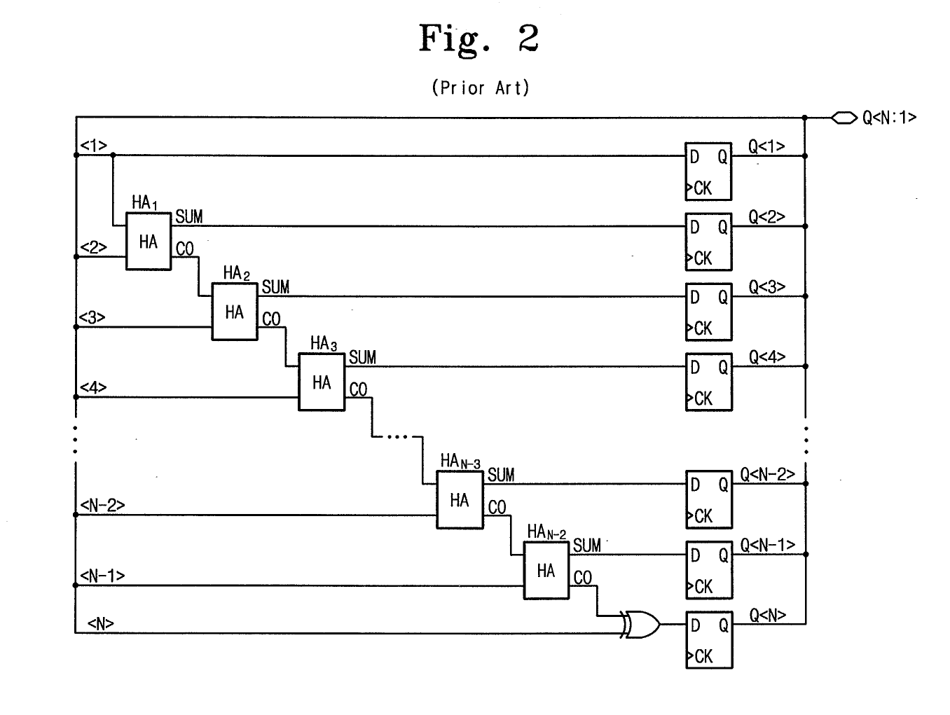

### DESCRIPTION OF PREFERRED EMBODIMENTS

In the following detailed description, several specific examples are set forth in order to provide a thorough understanding of the present invention. It should be understood, however, that the description of preferred embodiments is merely illustrative and that it should not be taken in a limiting sense.

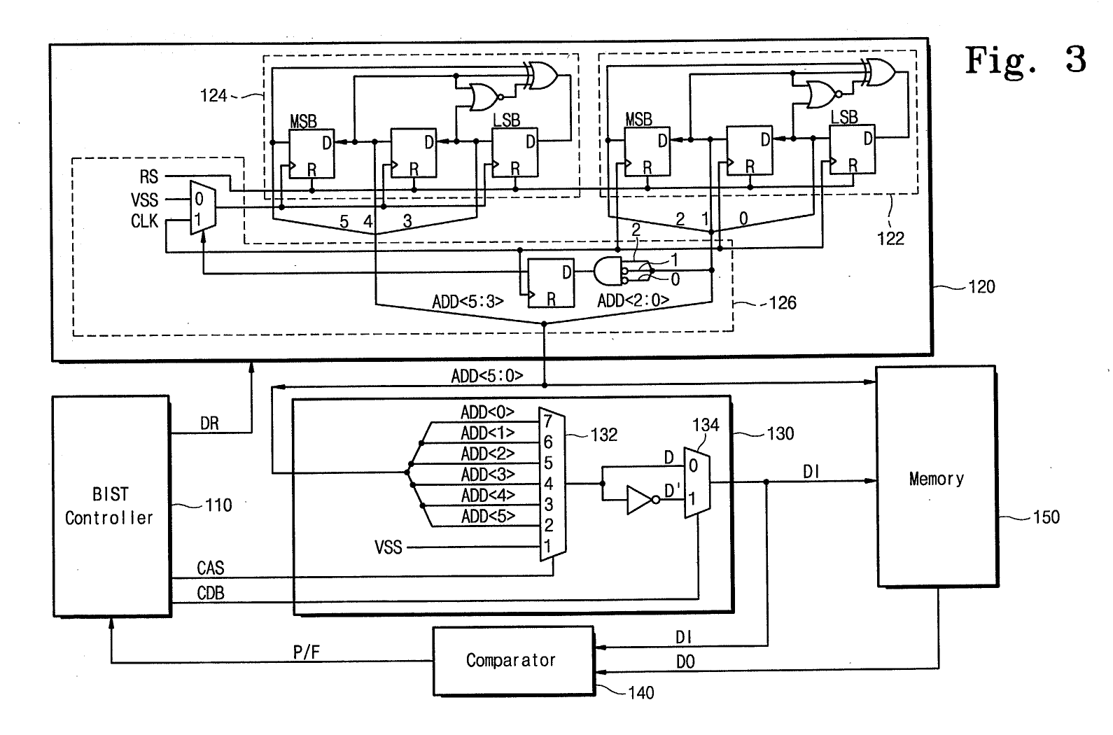

FIG. 3 shows a semiconductor integrated device comprising a BIST circuit according to an embodiment of the invention. Referring to FIG. 3, the BIST circuit comprises a BIST controller 110, an address generator 120, a data generator 130, and a comparator 140. The BIST controller 110 comprises a single-order address test algorithm for counting address data backgrounds (ADB) of address bits to perform a self-test of a memory 150. The ADB is defined as available combinations of all the data that may be assigned to two memory cells having different addresses. The BIST controller 110 produces control signals such as DR, a current ADB information signal (CAS), and a complemented data background signal (CDB) for controlling components of the BIST circuit.

In one embodiment, the address generator 120 comprises of serially connected first and second linear feedback shift registers (LFSRs) 122 and 124, and an LFSR controller 126. The first and second LFSRs 122 and 124 comprise a counter to produce single-order pseudo-random address patterns comprising, for example, address bits ADD<5:0> which are used to read and write data from and to the memory 150. The LFSR controller 126 controls the counting operation of the first and second LFSRs 122 and 124 to determine upper bits and lower bits of the produced single-order pseudo-random address patterns.

The data generator 130 comprises a first multiplexer 132 and a second multiplexer 134 to produce test data DI that comprises data within the address data backgrounds of the address bits ADD<5:0>. For example, the first multiplexer 132 receives a ground voltage (VSS) and address bits ADD<5:0> as input data, and then selects one of the input data values, i.e., ADD<5:0> and VSS in response to the current ADB information signal CAS. The second multiplexer 134 passes or inverts an output of the first multiplexer 132 in response to the complemented data background signal CDB to produce the test data DI.

The test data DI is written to a memory cell of memory 150 corresponding to the test address. The comparator 140 compares the test data DI with memory data DO read from the memory 150 to produce a detection signal P/F (Pass/Fail). The detection signal P/F is applied to the BIST controller 110. The detection signal is active depending on a predetermined condition. For example, the detection signal may be active upon coincidence of the two data DL and DO and inactive when the two data DL and DO are not coincident.

In the exemplary embodiment, the address generator 120 is constructed to generate 64(=2⁶) address patterns with the 6-bit address bits ADD<5:0> by using the LFSRs 122 and 124 and the LFSR controller 126, but it is understood that the number of the address patterns can be adjusted based on the number of address bits. Advantageously, the two LFSRs can be implemented to produce the 64 address patterns and perform a check operation for a normal mode and a test mode by a segment unit without preliminary evaluating operations of 64 LFSRs. The address generator 120 may comprise a plurality of serial-connected LFSRs comprising the same number of output bits or the different number of output bits.

In general, a LFSR can advantageously produce a desired amount of data combinations with given binary bits, while operating at high speed and occupying a smaller area. However, since the LFSR produces random address patterns instead of sequential address patterns, as described in Michael Kohn Sebastian Smith, “Application-specific integrated circuits”, Addison Wesley Publishing Company, 1997, 14.7.1, it is impossible to apply the “March test algorithm” most adaptable for a BIST circuit using the LFSR. Indeed, the LFSR cannot make reversed decrement address patterns such as “8-6-4-2-7-5-3-1” to increment address patterns such as “1-3-5-7-2-4-6-8”, which are required in the March test algorithm. Therefore, a BIST circuit according to a preferred embodiment of the present invention preferably employs a single-order test algorithm as disclosed in U.S. Pat. No. 5,706,293, issued in 1998 to Kim et al., entitled Method of testing single-order address memory, which is incorporated herein by reference. Briefly, a single-order test algorithm is as follows.

↑(W_{D})↑(R_{D},W_{D}′)↑(R_{D}′,W_{D})↑(R_{D})

The arrow key “↑” indicates a direction of address-counting, i.e., an address increment. W and R respectively indicate a writing operation and a reading operation. Subscripts _{D} and _{D}′ respectively indicate a fixed data value and its inversion value. The symbol “( )” indicates a sequential process without an address change, and the symbol “,” demarcates the writing operation and the reading operation.

The single-order test algorithm performs single-order address counting procedures that are adaptable for a LFSR counter for generating address patterns for high speed operation while utilizing a smaller area on the integrated circuit.

FIGS. 4A and 4B are exemplary diagrams showing seven groups of address data backgrounds ADB1 to ADB7 of 64 addresses ADD (that are produced with 6 address bits, e.g., ADD<5:0>). The memory addresses ADD comprise seven groups of address data backgrounds ADB1 to ADB7, which are established by a design rule using a parametric formula log₂N+1. The numeric reference “D” indicates a fixed value of the test data DI produced with the test algorithm, and D′ indicates the complementary value of D.

FIG. 5 is a diagram showing test addresses produced by the combination of ADD<2:0> and ADD<5:3>, using two 3-bit LFSRs, e.g., the first and second LFSRs122 and 124 of FIG. 3. For example, the first LFSR 122 produces LFSR0 comprising the lower three bits ADD<2:0> of the six bits ADD<5:0> in the iterative order of 000, 001, 010, 101, 011, 111, 110, and 100. The second LFSR 124 produces LFSR1 comprising the upper three bits ADD<5:3> of the six bits ADD<5:0>, in the iterative order of 000, 001, 010, 101, 011, 111, 110, and 100.

Returning to FIG. 3, the data generator 130 produces the test data DI in response to the address bits ADD<5:0> output from the address generator 120. For example, the first multiplexer 132 receives VSS, ADD<5>, ADD<4>, ADD<3>, ADD<2>, ADD<1>, and ADD<0> (which correspond to one of the seven groups of address data backgrounds ADB1, ADB2, ADB3, ADB4, ADB5, ADB6, and ADB7, respectively) as input values, and then outputs one of the input values in response to the current ADB information signal CAS. The second multiplexer 134 passes or inverts the output value of the first multiplexer 132 to produce the test data DI in response to the complemented data background signal CDB.

As described above, the data generator 130 produces the test data DI in response to each of the address bits generated from the LFSRs of the address generator 120. For instance, when 64 address patterns are generated by the address generator 120 with six address bits, the data generator 130 requires seven groups of address data backgrounds corresponding to the ADD<0> to ADD<5> and VSS. The data generator 130 selects one of the six address bits and a corresponding group of the six groups of the address data backgrounds ADB2 to ADB7 (which are produced by the single-order test algorithm), or selects either all “0” (zero) or all “1” (one) according to the first group of the address data background ADB1. Assuming that a current background group is ADB2 and a test address is “010 110”, the data generator 130 outputs “0” and “1” respectively as D and D′ (refer to the state of the 22'th address in FIG. 4A). On the other hand, when a current background group is ADB6 and a test address is “010 001”, the data generator 130 outputs “0” and “1” respectively as D and D′ (refer to the state of the 17'th address in FIG. 4).

According to a preferred embodiment of the present invention, a BIST circuit employs a plurality of serial-connected LFSRs to produce single-order pseudo-random address patterns, and thus, enable the circuit to operate in high speed without enlarging a circuit area in a semiconductor integrated device. Advantageously, a BIST circuit according to the invention can test large-size addresses with smaller-size address patterns without counting all addresses to be tested, thereby enhancing a test speed and reducing test time. Moreover, because an address generator according to a preferred embodiment of the present invention comprises a plurality of serial-connected LFSRs to count address bits, normal and test operations of the address generator can be easily performed. The number of LFSRs may be modified in accordance with an operation speed of a chip and an address size.

Although preferred embodiments of the present invention have been disclosed for illustrative purposes, those skilled in the art will appreciate that various modifications, additions and substitutions are possible, without departing from the scope and spirit of the invention as detailed by the accompanying claims

What is claimed is:

1. A BIST (built-in self test) circuit comprising:
a controller for controlling a self-testing operation of a memory chip embedded in an integrated circuit;
an address generator for generating pseudo-random address patterns under control of the controller;
a data generator for producing test data associated with data backgrounds of the address bits under the control of the controller; and
a comparator for comparing the test data with memory data output from the memory chip to detect, a defect, if any, of the memory chip.

2. The circuit of claim 1, wherein the controller operates using an algorithm that counts the data backgrounds of the address bits in a single-order.

3. The circuit of claim 1, wherein the address generator comprises:
a plurality of linear feedback shift registers (LFSRs) serially connected to each other for producing the pseudo-random address patterns, the pseudo-random address patterns being single-order pseudo-random address patterns; and
a register controller for controlling the plurality of LFSRs. .

4. The circuit of claim 3, wherein the a plurality of LFSRs comprise a counter for counting the address bits to produce the pseudo-random address patterns.

5. The circuit of claim 1, wherein the data generator comprises:
a first multiplexer for receiving the address bits and a ground voltage as input values and selecting one of the input values in response to a first control signal from the BIST controller; and
a second multiplexer for producing the test data from the output of the first multiplexer, in response to a second control signal from the controller.

6. The circuit of claim 5, wherein the first control signal comprises a current data background of the address bits, and the second control signal comprises a complemented data background of the address bits.

7. The circuit of claim 1, wherein the address generator comprises:
a first linear feedback shift register for producing a first group of the pseudo-random address patterns by counting the address bits;
a second linear feedback shift register, serially connected to the first linear feedback shift register, for producing a second group of the pseudo-random address patterns by counting the address bits; and
a register controller for controlling the first and second linear feedback shift registers such that the first linear feedback shift register counts lower bits of the address bits and the second linear feedback shift register counts upper bits of the address bits or the first linear feedback shift register counts upper bits of the address bits and the second linear feedback shift register counts lower bits of the address bits.

8. The circuit of claim 7, wherein the pseudo-random random pattern comprises a single-random pseudo-random address pattern.

9. The circuit of claim 7, wherein the second linear feedback shift register produces the second group of the pseudo random address patterns whenever the first linear feedback shift register produces all the first group of the pseudo random address patterns.

10. The circuit of claim 1, wherein the data background of the address bits comprises data combinations that two random memory cells having mutually different addresses have.

11. A method for performing self-testing operation on a memory chip embedded in an integrated circuit, comprising the steps of:
counting address bits to produce test addresses of pseudo-random address patterns;
producing test data according to the test address and data backgrounds of the address bits; and
comparing the test data with memory data output from the memory chip to determine whether a defect exists.

12. The method of claim 11, wherein the step of counting the address bits comprises the step of counting the data backgrounds of the address bits in a single-order.

13. The method of claim 12, wherein the step of counting the address bits further comprises the steps of:
counting lower bits of the address bits to produce a first group of the pseudo-random address patterns; and
counting upper bits of the address bits to produce a second group of the pseudo-random address patterns.

14. The method of claim 11, wherein the step of producing the test data comprises the steps of:
receiving the address bits and a ground voltage as input values;
selecting one of the input values in response to a first signal, the first signal comprising information about a current data background of the address bits; and
producing the test data in response to the selected input value and a second signal, the second signal comprising information about a complemented data background of the address bits.
